(19) United States
(12) Patent Application Publication
(10) Pub. No.: US 2008/0150038 A1
(43) Pub. Date: Jun. 26, 2008

(54) Method of fabricating semiconductor device

(75) Inventor: Min Ho Jeong, Seoul (KR)

Correspondence Address: WORKMAN NYDEGGER, 60 EAST SOUTH TEMPLE, 1000 EAGLE GATE TOWER, SALT LAKE CITY, UT, 84111, US

(73) Assignee: DONGBU HITEK CO., LTD., Seoul (KR)

(21) Appl. No.: 11/953,608

(22) Filed: Dec. 10, 2007

(30) Foreign Application Priority Data
Dec. 20, 2006 (KR) 10-2006-0130622

(51) Int. Cl. H01L 29/78; H01L 21/336

(52) U.S. Cl. 257/384; 438/296; 257/E29.255; 257/E21.409

(57) ABSTRACT

Semiconductor devices may be fabricated according to a method that includes steps of forming isolation layers in and a gate electrode on a semiconductor substrate and forming sidewall spacers on both sides of the gate electrode. Ions may be implanted into the semiconductor substrate by using the gate electrode and the sidewall spacers as masks, forming barriers to limit diffusion of impurities. Impurity ions may be implanted for source/drain into the barriers, thus forming source/drain impurity diffusion regions. Thus, when annealing after ion implantation to form the source/drain impurity diffusion regions, impurities can be prevented from diffusing downward too far. Accordingly, a short between neighboring source/drain impurity diffusion regions can be prevented when voltage is applied to the semiconductor device, the depths of source/drain impurity diffusion regions can be decreased, and a line width can be miniaturized.

### CROSS-REFERENCE TO RELATED APPLICATION

This application claims priority to Korean Application No. 10-2006-0130622, filed on Dec. 20, 2006, which is incorporated herein by reference in its entirety.

### BACKGROUND

1. Field of the Invention

The present invention relates, in general, to semiconductor devices and a method of fabricating semiconductor devices. More particularly, the present invention relates to semiconductor devices and a related method of fabrication in which, when annealing after ion implantation to form source/drain impurity diffusion regions, impurities, called dopants, can be prevented from diffusing downward too far. Because dopants of the source/drain impurity diffusion regions are prevented from diffusing downward too far, a short can be prevented between neighboring source/drain impurity diffusion regions (i.e., a short channel effect) when voltage is applied.

2. Background of the Invention

In connection with higher integration and miniaturization of semiconductor devices, there is an increasing need to reduce the defects of semiconductor devices by decreasing the adverse effect of the short channel effect. Therefore, thinner source/drain impurity diffusion regions are needed to avoid or limit the short channel effect.

In particular, in recent years, in relation to high integration, there is a need for a source/drain impurity diffusion region formed to a depth of 50 nm or less on a semiconductor substrate.

However, the method of forming the source/drain impurity diffusion region on the semiconductor substrate is carried out by annealing after ion implantation, and, therefore, an accurate profile of the source/drain impurity diffusion region cannot be obtained.

This is because, in the step of activating a source/drain impurity diffusion region by annealing, ion-implanted impurities are diffused downward, increasing likelihood of a short between the source/drain impurity diffusion regions or between the impurities and neighboring source/drain impurity diffusion regions.

### SUMMARY OF SOME EXAMPLE EMBODIMENTS

It is, therefore, an object of the present invention to provide semiconductor devices and a method of fabricating semiconductor devices, in which at the time of annealing after ion implantation for forming source/drain impurity diffusion regions, impurities or dopants can be prevented from diffusing downward too far. Because dopants of the source/drain impurity diffusion regions are prevented from diffusing downward too far, a short can be prevented between neighboring source/drain impurity diffusion regions when voltage is applied, and the depths of the source/drain impurity diffusion regions can be decreased, enabling miniaturization of a line width.

In accordance with example embodiments, there is provided a method of fabricating semiconductor devices and a semiconductor device formed by the method. The method may include the steps of forming isolation layers in and a gate electrode on a semiconductor substrate, and forming sidewall spacers on both sides of the gate electrode. Ions may then be implanted into the semiconductor substrate by using the gate electrode and the sidewall spacers as masks, forming barriers to limit diffusion of impurities. Next, impurity ions may be implanted for source/drain into the barriers to form source/drain impurity diffusion regions.

### BRIEF DESCRIPTION OF THE DRAWINGS

Aspects of example embodiments of the invention will become apparent from the following description of example embodiments given in conjunction with the accompanying drawings, in which:

FIGS. 1a to 1f are cross-sectional views illustrating a method of fabricating semiconductor devices in accordance with the present invention.

### DETAILED DESCRIPTION OF SOME EXAMPLE EMBODIMENTS

Hereinafter, aspects of example embodiments of the present invention will be described in detail with reference to the accompanying drawings so that they can be readily implemented by those skilled in the art.

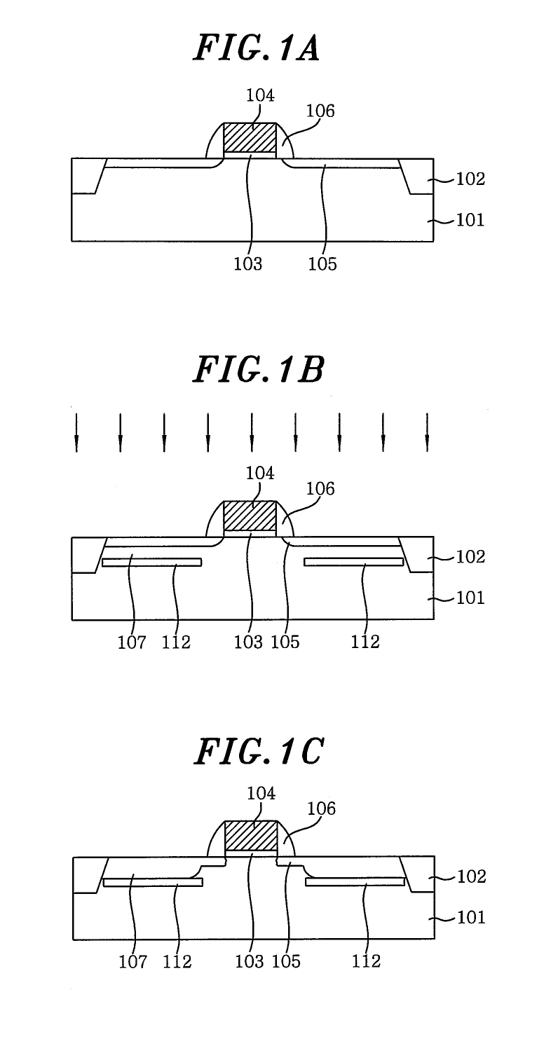

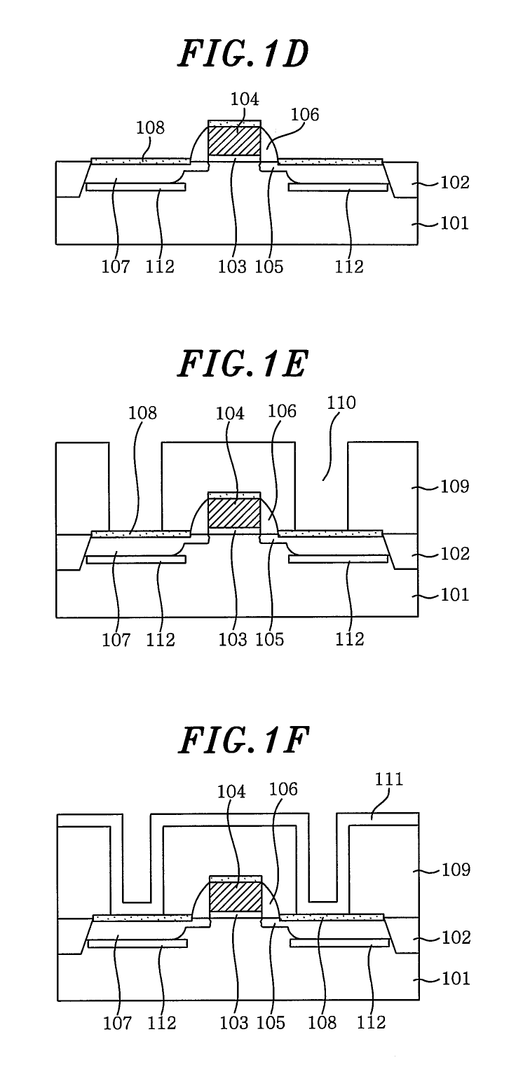

FIGS. 1a to 1f are cross-sectional views illustrating an exemplary method of fabricating semiconductor devices. The method of fabricating a semiconductor device may include the steps of forming an isolation layer, a gate electrode, and a sidewall spacer over a semiconductor substrate, forming barriers within the semiconductor substrate, and forming source/drain impurity diffusion regions over the barriers.

Referring to FIG. 1a, in the step of forming the isolation layer and the gate electrode, and the sidewall spacer over the semiconductor substrate, isolation layers 102 having a shallow trench isolation (STI) structure may be formed in specific regions of a semiconductor substrate 101. For example, the isolation layers 102 can be formed by forming trenches having a specific depth in the semiconductor substrate and gap-filling the trenches with gap-fill material.

A gate insulating layer 103 may be formed on the entire surface of the semiconductor substrate 101 including the isolation layers 102. A polysilicon layer (not shown) may be formed on the gate insulating layer 103. A photolithography process and an etch process may be formed on the polysilicon layer and the gate insulating layer 103 in order to selectively etch them, so that a gate electrode 104 is formed over the semiconductor substrate 101 between the isolation layers 102.

Low-concentration impurity ions may be implanted into the entire surface of the semiconductor substrate 101 by using the gate electrode 104 as a mask, thus forming lightly doped drain (LDD) regions 105 in the semiconductor substrate 101 on both sides of the gate electrode 104.

An insulating layer may be formed over the entire surface of the semiconductor substrate 101 including the gate electrode 104. The insulating layer can be formed from a silicon oxide (SiO) layer or a silicon nitride (SiN) layer.

An etch-back process may be performed on the entire surface of the insulating layer, so that sidewall spacers 106 are formed on both sides of the gate electrode 104.

Referring to FIG. 1b, in the step of forming the barriers within the semiconductor substrate, ions may be implanted under portions of the semiconductor substrate 101, in which source/drain impurity diffusion regions will be located, by using the gate electrode and the sidewall spacer as masks, thus forming barriers 112.

The barriers 112 may thus be located under the source/drain impurity diffusion regions, which will be formed by a subsequent process, so that impurity ions for source/drain can be prevented from diffusing downward too far.

Meanwhile, in the step of forming the barriers, nitrogen ions may be implanted in order to form the barriers 112 from nitride.

Referring to FIG. 1c, in the step of forming the source/drain impurity diffusion regions over the nitride barriers, the impurity ions for the source/drain may be implanted over the nitride barriers 112 of the semiconductor substrate 101 by using the gate electrode 104 and the sidewall spacer 106 as masks. Thus source/drain impurity diffusion regions 107, connected to the LDD regions 105, may be formed in the semiconductor substrate 101 on both sides of the gate electrode 104. The nitride barriers 112 may serve as layers to prevent impurity atoms from diffusing downward too far if the source/drain are annealed.

Referring to FIG. 1d, high-melting point metal may be deposited over the entire surface of the semiconductor substrate 101 including the gate electrode 104. An annealing process may be performed on the entire surface to form metal silicide layers 108 on the gate electrode 104 and the source/drain impurity diffusion regions 107.

Referring to FIG. 1e, an interlayer insulating layer 109 may be deposited over the entire surface of the semiconductor substrate 101. Interlayer insulating layer 109 may then be selectively removed so that specific regions of the source and the drain impurity diffusion regions 107 are exposed, thus forming contact holes 110.

Referring to FIG. 1f, TiN, Ta, TaN, WN_{X} or TiAl(N) may be deposited over the entire surface of the semiconductor substrate 101 including the contact holes 110 by a physical vapor deposition (VPO) or chemical vapor deposition (CVD) method, thus forming a barrier metal layer 111 having a thickness of 10 to 1000 angstrom.

Though subsequent processes are not illustrated, a metal layer may be deposited on the barrier metal layer 111 and may be selectively patterned to form metal lines.

As described above, the higher the degree of integration of semiconductor devices, the narrower the line width and the shorter the channel length will be. Thus, the diffusion of dopants implanted into neighboring source/drain impurity diffusion regions 107 may cause a short channel effect. However, the nitride barriers 112 can limit the downward diffusion of dopants implanted so as to form the source/drain impurity diffusion regions 107.

Furthermore, since the diffusion of impurity ions implanted so as to form the source/drain impurity diffusion regions 107 is limited, a short can be prevented between neighboring source/drain impurity diffusion regions 107 having an isolation layer 102 positioned therebetween. It is therefore possible to secure reliability of semiconductor devices.

In addition, since the depth of the source/drain impurity diffusion regions 107, which become thin as a line width decreases, can be controlled by the nitride barrier 112, the source/drain impurity diffusion regions 107 can be formed at a desired depth.

In summary, a semiconductor device and a method of fabricating the semiconductor device according to exemplary embodiments, can limit downward diffusion of impurities when annealing after ion implantation to form the source/drain impurity diffusion regions. Accordingly, a short between neighboring source/drain impurity diffusion regions can be prevented when voltage is applied to the semiconductor device, the depths of source/drain impurity diffusion regions can be decreased, and a line width can be miniaturized.

While the invention has been shown and described with respect to the specific embodiment, it will be understood by those skilled in the art that various changes and modifications may be made without departing from the spirit and scope of the invention as defined in the following claims.

What is claimed is:

1. A method of fabricating a semiconductor device comprising the steps of:
forming isolation layers in and a gate electrode on a semiconductor substrate;
forming sidewall spacers on both sides of the gate electrode;
implanting ions into the semiconductor substrate by using the gate electrode and the sidewall spacers as masks, forming barriers to limit diffusion of impurities; and
implanting impurity ions for source/drain into the barriers to form source/drain impurity diffusion regions.

2. The method of claim 1, wherein in the step of forming the barriers, nitrogen ions are implanted to form nitride barriers.

3. The method of claim 1, further comprising the steps of:
forming metal silicide layers on the source/drain impurity diffusion regions;
depositing and selectively removing an interlayer insulating layer to form contact holes that expose at least a portion of the source/drain impurity diffusion regions; and
depositing a barrier metal layer on the interlayer insulating layer and the source/drain impurity diffusion regions, the barrier metal layer being selectively patterned to form metal lines.

4. The method of claim 1, further comprising the steps of:
implanting low-concentration impurity ions into the semiconductor substrate to form lightly doped regions in the semiconductor substrate.

5. A semiconductor device comprising:
isolation layers formed in and a gate electrode formed on a semiconductor substrate;
sidewall spacers formed on both sides of the gate electrode;
barriers to limit diffusion of impurities, formed by implantation of ions into the semiconductor substrate using the gate electrode and the sidewall spacers as masks; and
source/drain impurity diffusion regions formed by implantation of impurity ions for source/drain into the barriers.

6. The semiconductor device of claim 5, further comprising:
metal silicide layers formed on the source/drain impurity diffusion regions;
an interlayer insulating layer with contact holes that expose at least a portion of the source/drain impurity diffusion regions; and
a barrier metal layer deposited on the interlayer insulating layer and the source/drain impurity diffusion regions, the barrier metal layer being selectively patterned to form metal lines.

7. The semiconductor device of claim 5, further comprising:
lightly doped regions formed by implantation of low-concentration impurity ions into the semiconductor substrate.

8. The semiconductor device of claim 7, wherein the lightly doped regions extend under the sidewall spacers.
